(19) United States
(12) Patent Application Publication
(10) Pub. No.: US 2026/0304764 A1
(43) Pub. Date: Oct. 1, 2026

(54) PILLAR STRUCTURES IN TIER STACK TO REDUCE TIER DEFLECTION

(71) Applicant: MICRON TECHNOLOGY, INC., Boise, ID (US)

(72) Inventors: Kaiming Luo, Singapore (SG); Sriram Balasubramanian, Boise, ID (US); Martin Jared Barclay, Middleton, ID (US); Vladimir Samara, Boise, ID (US); Mark Swenson, Meridian, ID (US); Mohammad Reza Zamani Kouhpanji, Boise, ID (US); Yingqiao Wang, Boise, ID (US); Kyle Adam Ritter, Boise, ID (US); Thomas Jon Peterson, Boise, ID (US); Jeeno Jose, Kerala (IN); Sumeet Chandra Pandey, Meridian, ID (US); Hamid Ghasemi, Boise, ID (US); Saurabh Jagdishbhai Kasodariya, Hyderabad (IN); Martina Damayanti, Singapore (SG)

(21) Appl. No.: 19/092,216

(22) Filed: Mar. 27, 2025

(51) Int. Cl. H10B 43/27; H10B 41/10; H10B 41/27; H10B 43/10

(52) U.S. Cl. CPC H10B 43/27; H10B 41/10; H10B 41/27; H10B 43/10

(57) ABSTRACT

A method includes forming a tier stack of an electronic circuit including a plurality of tiers. A tier includes a first layer of a first dielectric material and a second layer of a second dielectric material. The method further includes forming a first pillar, a second pillar, and a third pillar each extending through at least a portion of the plurality of tiers. The first pillar is disposed between the second pillar and the third pillar. The method further includes selectively etching the second layer of the second dielectric material of each of the plurality of tiers to form a void within each of the plurality of tiers. The method further includes filling the void within each of the plurality of tiers with metal to form a plurality of conductive lines.

### TECHNICAL FIELD

Embodiments of the disclosure relate generally to memory sub-systems, and more specifically, relate to pillar structures in a tier stack to reduce tier deflection.

### BACKGROUND

A memory sub-system can include one or more memory devices that store data. The memory devices can be, for example, non-volatile memory devices and volatile memory devices. In general, a host system can utilize a memory sub-system to store data at the memory devices and to retrieve data from the memory devices.

### BRIEF DESCRIPTION OF THE DRAWINGS

The disclosure will be understood more fully from the detailed description given below and from the accompanying drawings of various embodiments of the disclosure. The drawings, however, should not be taken to limit the disclosure to the specific embodiments, but are for explanation and understanding only.

FIGS. 1A-E are schematic representations illustrating a method of manufacturing a memory array in accordance with some embodiments of the present disclosure.

FIGS. 2A and 2B are simplified top-down schematic representations of a memory array in accordance with some embodiments of the present disclosure.

FIGS. 3A-C are top-down representations of a memory array in accordance with some embodiments of the present disclosure.

FIG. 4 is a flow diagram of an example method of manufacturing a memory array in accordance with some embodiments of the present disclosure.

FIG. 5A illustrates an example computing system that includes a memory sub-system in accordance with some embodiments of the present disclosure.

FIG. 5B is a block diagram of a memory device in communication with a memory sub-system controller of a memory sub-system, according to an embodiment.

### DETAILED DESCRIPTION

Aspects of the present disclosure are directed to methods of forming conductive lines (e.g., wordlines) of a memory array to reduce tier deflection. Storage devices such as solid-state drives (SSDs) may include 3-dimensional (3D) NAND flash memory technology. Traditional NAND flash memory stores data in a 2-dimensional (2D) structure, where memory cells are laid out on a single layer of dielectric material. 3-dimensional (3D) NAND instead stacks memory cells vertically in multiple layers (hence the “3D” designation). Such vertical stacking allows for increased storage densities and greater storage capacity in a comparatively smaller physical footprint when compared to planar NAND. A key advantage of 3D NAND is its ability to continue increasing storage capacities while maintaining or even improving performance and reliability. 3D NAND technology has enabled the development of SSDs with larger capacities, faster speeds, and lower costs per unit of storage.

A 3D NAND device includes multiple memory cells stacked vertically in multiple tiers, such that an inner tier of the stack is adjacent to two neighboring tiers, while an outer tier of the stack is adjacent to one neighboring tier. In order to achieve higher storage capacities and/or improve performance of the device, the number of tiers within a single memory device may be increased, thus allowing for higher-capacity storage devices. However, the increase in the number of tiers also increases the overall height of the 3D NAND structure. To limit the height of the 3D NAND structure, the thickness of each tier can be decreased.

Each tier in a 3D NAND structure can include multiple layers. For example, a tier can include an oxide layer (e.g., a metalloid oxide layer such as a silicon oxide layer) and a nitride layer (e.g., a metalloid nitride layer such as a silicon nitride layer). To increase the number of tiers in a 3D NAND structure without increasing the overall height of the structure, the thickness of each layer in the tiers making up the 3D NAND structure can be decreased. However, as the layer thickness is decreased, tier deflection can be induced. Tier deflection is the deformation (e.g., deflection) of layers and/or other elements of a 3D NAND structure caused when intermediate supporting layers are removed. For example, to form wordlines in a layer stack of tiers, the nitride layers are selectively etched away to form voids in the tier stack. The adjacent layers (e.g., oxide layers) above and beneath each of the voids are then unsupported and may deflect or even break. In some embodiments, metal is provided into the voids (e.g., between oxide layers) to fill the voids and to form metal layers within the tier stack. Surface tension in the metal as the metal grows in the voids may additionally cause the adjacent oxide layers to deflect. Deflection of the oxide layers can lead to shorts and/or opens in the conductive lines, such as if the deflection leads to oxide layer breakage and/or closing off of the voids so that metal cannot enter. Additionally, the deflection of the oxide layers can lead to non-uniform thicknesses of conductive lines, which can cause defects and/or inefficiencies in the operation of the 3D NAND.

Aspects of the present disclosure may address the deficiencies described above and other challenges by providing pillar structures in a tier stack to reduce tier deflection during manufacturing of a 3D NAND structure. In some embodiments, a first pillar (e.g., an intermediate pillar, a diamond-shaped pillar, etc.) is formed between a second pillar and a third pillar during manufacturing of the 3D NAND. The oxide layers in the tier stack may span between pillars, which give structural support to the oxide layers. When the span (of the oxide layers) between pillars is too great, the oxide layers may deflect and/or break. Conventionally, only the second pillar and the third pillar are formed in a tier stack (i.e., the intermediate pillar is not included). Thus conventionally, the oxide layers in the tier stack span from the second pillar to the third pillar. In some embodiments, forming the intermediate pillar (e.g., the pillar between the second pillar and the third pillar) effectively reduces the span of the oxide layers in the tier stack. The oxide layers thus may span from the second pillar to the first pillar and from the first pillar to the third pillar. The first pillar, the second pillar, and the third pillar may support the oxide layers. Reducing the span which may reduce the stress and/or deflection of the oxide layers in the tier stack. Accordingly, when nitride layers are stripped from the tier stack to form voids (which are later filled with conductive metal to form conductive lines), the oxide layers are supported in the middle of their span by the intermediate pillar. Thus, deflection of the oxide layers may be reduced, reducing tier deflection generally.

In some embodiments, the intermediate pillar (e.g., the pillar formed between two or more other pillars) has a cross-section shaped such that the intermediate pillar does not interfere with adjacent pillar(s). For example, and in some embodiments, the intermediate pillar has a diamond-shaped cross-section (e.g., a substantially diamond-shaped cross-section). The diamond-shape may provide adequate space between other neighboring pillars so that the other features of the 3D NAND structure and/or their function(s) are unaffected. If the cross-section of the intermediate pillar is too close to a neighboring pillar, the intermediate pillar may adversely affect the function of the neighboring pillar, such as if the neighboring pillar is a contact for accessing conductive line(s). Additionally, in some embodiments, sufficient space is to be maintained between pillars to leave room for conductive lines. If too little space is included between pillars, the reliability of the conductive lines may be decreased.

In some embodiments, the intermediate pillar is formed in the tier stack during the formation of the contacts for accessing the conductive lines. However, the intermediate pillar may be a dummy contact in some embodiments. For example, the intermediate pillar may be formed while live contacts are formed, but may instead be formed using a non-conductive material (e.g., a dielectric material). The intermediate pillar may not be used for accessing conductive lines. Live contacts may be formed instead with a conductive material (e.g., such as a metal). At least some of the pillars neighboring the intermediate pillar may be live contacts. The live contacts may be used for accessing conductive lines. To form contacts (e.g., dummy contacts, live contacts, etc.), holes may be formed in the tier stack. Some of the holes may be filled with a dielectric material (e.g., a sacrificial dielectric material), thus forming dummy contacts. Some of the holes may be filled with a conductive material (e.g., a metal), thus forming live contacts. At least some of the pillars in the tier stack are dummy contacts. The dielectric material (e.g., of the dummy contacts forming the pillars) may structurally support the oxide layers of the tier stack when the adjacent nitride layers are removed (e.g., to form voids for later filling with metal to form the conductive lines). For example, and in some embodiments, the dielectric material of the pillars may provide stability, strength, rigidity, and/or reinforcement to the oxide layers. The pillars may ensure the oxide layers remain intact and/or the oxide layers deflect less than a threshold amount (e.g., less than an amount that may cause breakage). The structural support provided to the oxide layers by the intermediate pillar (e.g., reducing the span of the oxide layers) may substantially reduce and/or prevent tier deflection.

Advantages of the present disclosure include, for example, improved 3D NAND tier uniformity which can reduces the defect rate in a 3D NAND structure. By manufacturing a 3D NAND structure according to embodiments described herein, the thickness of each layer can be decreased without the undesired effects of tier deflection, thus allowing to increase the storage capacity without increasing the height of a 3D NAND structure. Moreover, the improved tier uniformity in a 3D NAND structure can improve the performance of a memory sub-system, leading to faster memory operations and/or decreased latency.

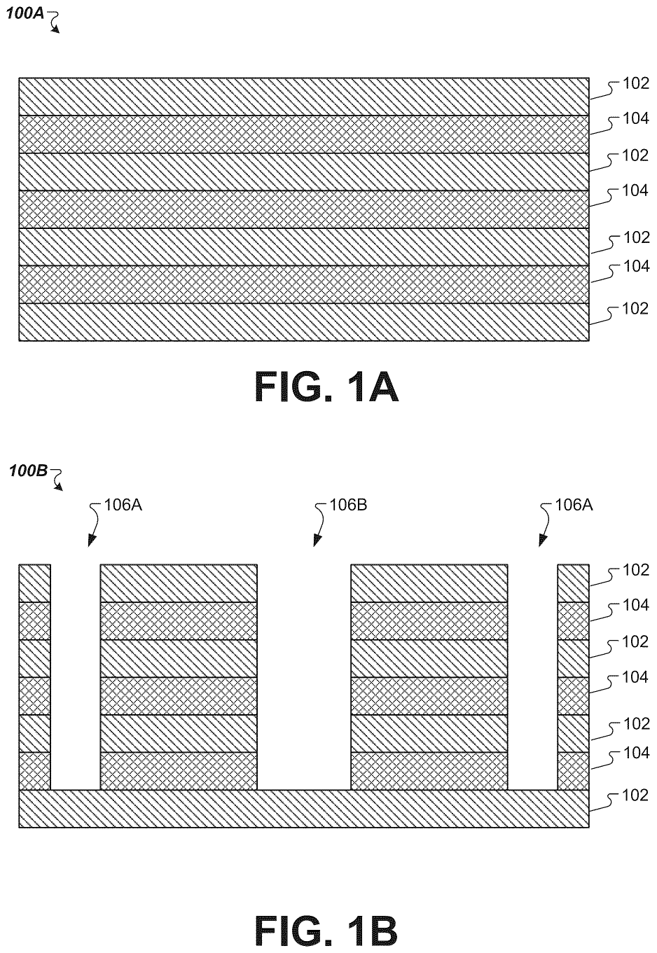

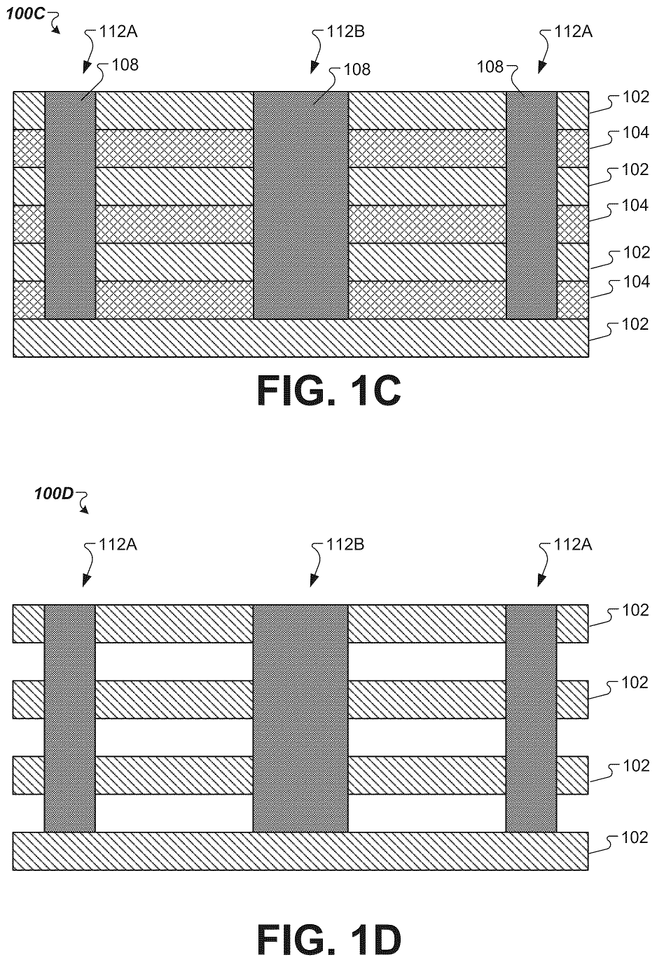

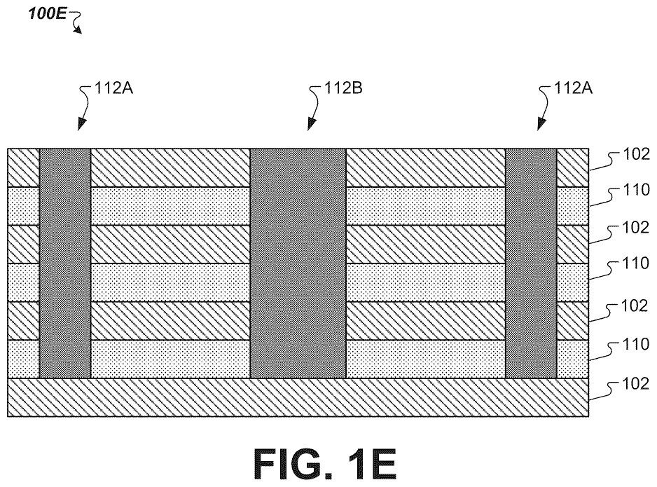

FIGS. 1A-E are schematic representations illustrating a method of manufacturing a memory array in accordance with some embodiments of the present disclosure. In some embodiments, each of FIGS. 1A-E illustrate a manufacturing operation for manufacturing a memory array with reduced tier deflection as described herein.

Referring to FIG. 1A, a representation of first operation 100A is shown. In some embodiments, a tier stack is formed. The tier stack may have multiple tiers stacked vertically such that an inner tier of the stack is adjacent to two neighboring tiers, while an outer tier of the stack is adjacent to one neighboring tier. A tier may be formed by multiple layers. For example, a tier may include a first layer 102 and a second layer 104. Each of the first layer 102 and the second layer 104 may be formed of a dielectric material. The tier stack may be formed by multiple (e.g., more than one, etc.) tiers stacked one on top of the other. Illustrated in FIG. 1A, three tiers are shown, although more tiers are possible. In some embodiments, layer 102 is a metalloid oxide layer, such as a silicon oxide layer. In some embodiments, layer 104 is a metalloid nitride layer, such as a silicon nitride layer.

In some embodiments, the stack of layers is formed by multiple deposition processes. For example, a first deposition process may be performed to deposit a first oxide layer 102, a second deposition process may be performed to deposit a first nitride layer 104, a third deposition process may be performed to deposit a second oxide layer 102, etc. The cycle of deposition processes described above may be repeated until the stack is complete. A completed stack may include many tiers, such as up to or more than one hundred tiers, etc.

Referring to FIG. 1B, a representation of a second operation 100B is shown. In some embodiments, holes or recesses 106A,B are formed in the tier stack. The recesses 106A,B may be orthogonal to the layers 102 and layers 104. The recesses 106A,B may extend through at least a portion of the tiers. For example, the recesses 106A,B may extend through multiple layers, but may not extend through all layers. In some embodiments, the recesses 106A,B are formed by performance of an etching process. The etching process may be a wet etch process or a dry etch process. In some embodiments, an etchant (e.g., a wet etchant or a dry etchant) is introduced to the top of the tier stack to etch through the layers 102 and 104 to form the recesses 106A,B. In some embodiments, the cross-sectional shape of the recesses 106A,B is controlled by a mask layer (not shown). The mask layer may be patterned to correspond with the cross-sectional shapes of the recesses 106A,B before the recesses 106A,B are etched. In some embodiments, photolithography is used to form a pattern on the mask layer. The pattern may correspond to the target cross-sectional shapes of the features to be formed in the tier stack (e.g., the recesses 106A,B). After forming the recesses 106A,B, the mask layer may be removed.

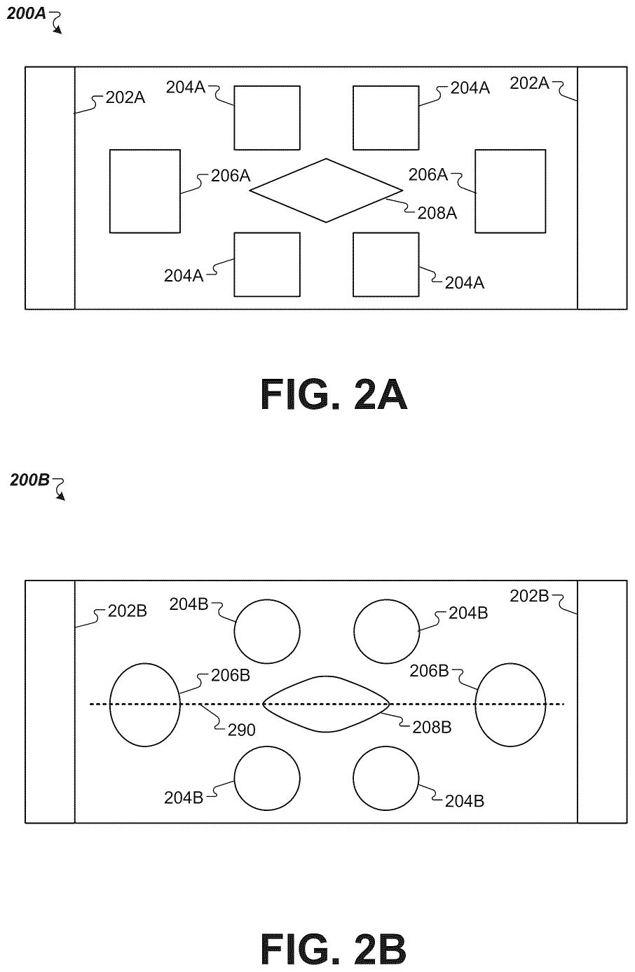

The recess 106B may be disposed between the recesses 106A. In some embodiments, the recess 106B has a diamond-shaped cross-section (e.g., substantially diamond-shaped cross-section). The recesses 106A may have a circular-shaped cross-section (e.g., substantially circular-shaped cross-section), a square-shaped cross-section (e.g., substantially square-shaped cross-section), or a rectangular-shaped cross-section (e.g., substantially square-shaped cross-section). In some embodiments, the recesses 106A,B are formed based on target cross-sectional shapes. However, due to imperfections in etching process(es), the actual formed cross-sectional shapes of the recesses 106A,B may be rounded when compared to the target cross-sectional shapes. Further details regarding the target cross-sectional shapes and actual cross-sectional shapes of the recesses 106A,B are discussed herein below with respect to FIGS. 2A and 2B.

Referring to FIG. 1C, a representation of a third operation 100C is shown. In some embodiments, the recesses 106A,B are filled with a dielectric material 108, forming pillars 112A,B. The pillars 112A,B may be formed extending through at least some of the layers 102 and 104. In some embodiments, the pillars 112A,B are orthogonal (e.g., substantially orthogonal) to the layers 102 and 104. The dielectric material 108 may be a sacrificial material used in semiconductor manufacturing, such as silicon oxide (e.g., silicon dioxide (SiO₂)), a polymer, amorphous silicon (a-Si), or silicon nitride (Si₃N₄), etc. In some embodiments, the dielectric material 108 is carbon or poly-silicon (e.g., polycrystalline silicon).

In some embodiments, the dielectric material 108 is deposited in the recesses 106A,B using a deposition process such as physical vapor deposition (PVD), atomic layer deposition (ALD), chemical vapor deposition (CVD), or another suitable deposition process. The pillars 112A,B may conform to the cross-sectional shape of the recesses 106A,B. For example, and in some embodiments, pillars 112A may have a circular-shaped cross-section (e.g., substantially circular-shaped cross-section), a square-shaped cross-section (e.g., substantially square-shaped cross-section), or a rectangular-shaped cross-section (e.g., substantially square-shaped cross-section), corresponding to the cross-sectional shape of recesses 106A. Similarly, in some embodiments, pillar 112B has a diamond-shaped cross-section (e.g., substantially diamond-shaped cross-section) corresponding to the cross-sectional shape of recess 106B. The cross-sectional shapes of pillars 112A,B may correspond to the actual cross-sectional shapes of the recesses 106A,B (e.g., rather than to the target cross-sectional shapes).

Referring to FIG. 1D, a representation of a fourth operation 100D is shown. In some embodiments, the nitride layers 104 are selectively etched, leaving voids between the oxide layers 102. An etching operation may be performed to selectively etch the nitride layers 104 selective to the oxide layers 102 to remove at least some of the nitride layers 104 from the tier stack. The etching operation may be performed to etch silicon nitride without etching silicon oxide. In some embodiments, one or more process chemistries are introduced to the layers 104 to etch the layers 104. Such process chemistries may include hydrofluoric acid (HF), phosphoric acid (H₃PO₄), hot potassium hydroxide (KOH), and/or tetramethylammonium hydroxide (TMAH).

The absence of the nitride layer 104 between the oxide layers 102 may cause the oxide layers 102 to be at least partially unsupported. In some embodiments, structural support for the oxide layers 102 is provided by the pillars 112A,B. For example, and in some embodiments, the pillars 112A,B form at least part of a structural support system within the tier stack. The structural support system may provide stability, strength, rigidity, and/or reinforcement to the oxide layers 102. The pillars 112A,B may support the oxide layers 102 so that the oxide layers 102 do not collapse on top of one another. Additionally, the pillars 112A,B may provide the oxide layers 102 so that the oxide layers 102 do not deflect due to stresses (e.g., shear and/or bending stresses, etc.) in the oxide layers 102. If the pillar 112B were absent, the each of the oxide layers 102 would span between the pillars 112A. The span between the pillars 112A may be too great for the oxide layers 102 without deflecting. For example, the shear and/or bending stresses in the oxide layers 102 may cause the oxide layers to deflect The deflection of the oxide layers 102 could lead to structural damage. However, by including pillar 112B, the span of the oxide layers 102 may be reduced, reducing the shear and/or bending stresses in the oxide layers 102 and thus reducing the deflection of the oxide layers 102. In some embodiments, deflection of the oxide layers 102 is reduced in excess of 50% when compared to the deflection absent the pillar 112B. In some embodiments, deflection of the oxide layers 102 is reduced approximately 57% when compared to the deflection absent the pillar 112B.

Referring to FIG. 1E, a representation of a fifth operation 100E is shown. In some embodiments, the void in each of the tiers formed by the selective etching of nitride layer 104 is back-filled with conductive material. In some embodiments, a metal layer 110 is formed between each of the oxide layers 102. In some embodiments, a gas phase reaction mechanism (e.g., such as a CVD technique, or another suitable technique) is used to deposit metal between each of the layers 102. In some embodiments, the metal is a conductive material (e.g., metal) such as molybdenum, a molybdenum alloy, tungsten, and/or a tungsten alloy, etc. In some embodiments, each of the metal layers 110 is to form a conductive line in the tier stack. The conductive lines may be wordlines, such as in a memory array.

FIGS. 2A and 2B are simplified top-down schematic representations of a memory array in accordance with some embodiments of the present disclosure. FIG. 2A illustrates target cross-sectional shapes of memory array features in accordance with some embodiments of the present disclosure. FIG. 2B illustrates actual cross-sectional shapes of memory array features in accordance with some embodiments of the present disclosure. The features of the memory array shown in FIG. 2B may be formed according to the target cross-sectional shapes shown in FIG. 2A.

Referring to FIG. 2A, a memory array 200A is shown having features with target cross-sectional shapes. In some embodiments, trenches 202A are formed parallel to one another on the memory array. The trenches may define boundaries of memory cells and/or boundaries of the memory array. In some embodiments, multiple live contacts 204A are formed in the memory array. The live contacts 204A may be conductive electrical contacts for accessing memory cell(s). The live contacts 204A may extend through the layers of the memory array. The live contacts 204A may extend orthogonally (e.g., substantially orthogonally) through the layers of the memory array. In some embodiments, the live contacts 204A have a square target cross-sectional shape or a rectangular target cross-sectional shape. In some embodiments multiple dummy contacts 206A are formed in the memory array. The dummy contacts 206A may correspond to pillars 112A in FIGS. 1C-E. The dummy contacts 206A may extend through the layers of the memory array. In some embodiments, the dummy contacts 206A extend orthogonally (e.g., substantially orthogonally) through the layers of the memory array. In some embodiments, the dummy contacts 206A have a square target cross-sectional shape or a rectangular target cross-sectional shape. Each of the dummy contacts 206A and/or the live contacts 204A may form pillars in the memory array.

In some embodiments, a diamond-shaped pillar 208A is formed in the memory array. The diamond-shaped pillar 208A may correspond to pillar 112B in FIGS. 1C-E. The diamond-shaped pillar 208A may extend through the layers of the memory array. In some embodiments, the diamond-shaped pillar 208A has a diamond target cross-sectional shape. The diamond-shaped pillar 208A may be disposed between the dummy contacts 206A and/or between the live contacts 204A. In some embodiments, the diamond-shaped pillar 208A is formed mid-way between the dummy contacts 206A and/or mid-way between adjacent sets of live contacts 204A.

The diamond-shaped pillar 208A may have a diamond cross-sectional shape so that the diamond-shaped pillar 208A does not interfere with the live contacts 204A and/or the dummy contacts 206A. There may be a minimum distance between the diamond-shaped pillar 208A and the live contacts 204A and/or the dummy contacts 206A. For example, to ensure there is sufficient space around the live contacts 204A and/or the dummy contacts 206A, the diamond-shaped pillar 208A has the diamond shape. Although each of the features described above (e.g., the trenches 202A, the live contacts 204A, the dummy contacts 206A, the diamond-shaped pillar 208A) have a target cross-sectional shape, limitations of etching process(es) dictate these features are formed having rounded shapes. The rounding of the shapes may be caused by intermediate photolithography process(es) (e.g., where target features are rounded when formed) and/or by etching process(es) (e.g., where etchants etch target features but with rounded corners, etc.).

Referring to FIG. 2B, a memory array 200B is shown with features formed based on the target cross-sectional feature shapes of memory array 200A. In some embodiments, the features are formed having rounded corners and/or rounded shapes, etc. However, the trenches 202B may have substantially square/straight defining features. In some embodiments, the live contacts 204B have a circular, ovular, or ellipsoidal cross-sectional shape. In some embodiments, the dummy contacts 206B have a circular, ovular, or ellipsoidal cross-sectional shape. In some embodiments, the diamond-shaped pillar 208B has a substantially diamond-shaped cross-section. The cross-section of the diamond-shaped pillar 208B may have at least partially rounded corners. The corners closest to the dummy contacts 206B (e.g., the left and right corners as illustrated) may be rounded less than the upper and lower corners. A cross-section 290 of the memory array (e.g., the dashed horizontal line shown in the figure) may correspond to the cross-section(s) shown in FIGS. 1A-E and described herein above.

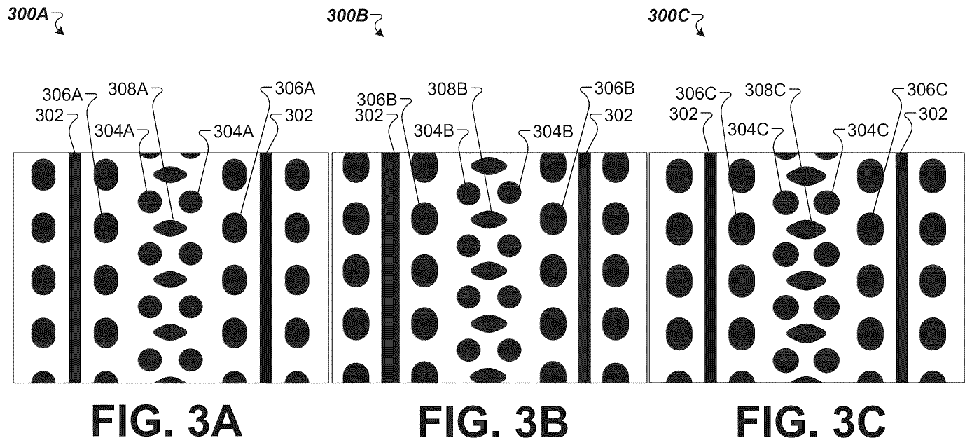

FIGS. 3A-C are top-down representations of a memory array in accordance with some embodiments of the present disclosure. Each of FIGS. 3A-C illustrate a memory array having features of different sizes. For example, FIG. 3A illustrates a memory array having small-sized features, FIG. 3B illustrates a memory array having medium-sized features, and FIG. 3C illustrates a memory array having large-sized features. However, in each of FIGS. 3A-C, trenches 302 may have the same size (e.g., substantially the same size).

Referring to FIG. 3A, a memory array 300A is shown. Memory array 300A may include features such as trenches 302, live contacts 304A, dummy contacts 306A, and/or diamond-shaped pillars 308A. In some embodiments, the diamond-shaped pillar 308A has a width (e.g., the left-to-right dimension as illustrated) between approximately 550 nanometers and approximately 600 nanometers and a height (e.g., the top-to-bottom dimensions as illustrated) between approximately 290 nanometers and approximately 340 nanometers. In some embodiments, the minimum distance between the diamond-shaped pillar 308A and the adjacent live contacts 304A is between approximately 140 nanometers and approximately 160 nanometers. The dimensions of the live contacts 304A and/or the dummy contacts 306A may be commensurate with the dimensions of the diamond-shaped pillar 308A.

Referring to FIG. 3B, a memory array 300B is shown. Memory array 300B may include features such as trenches 302, live contacts 304B, dummy contacts 306B, and/or diamond-shaped pillars 308B. The features of memory array 300B may be larger than the features of memory array 300A. In some embodiments, the diamond-shaped pillar 308B has a width (e.g., the left-to-right dimension as illustrated) between approximately 690 nanometers and approximately 740 nanometers and a height (e.g., the top-to-bottom dimensions as illustrated) between approximately 310 nanometers and approximately 360 nanometers. In some embodiments, the minimum distance between the diamond-shaped pillar 308B and the adjacent live contacts 304B is between approximately 130 nanometers and approximately 160 nanometers. The dimensions of the live contacts 304B and/or the dummy contacts 306B may be commensurate with the dimensions of the diamond-shaped pillar 308B.

Referring to FIG. 3C, a memory array 300C is shown. Memory array 300C may include features such as trenches 302, live contacts 304C, dummy contacts 306C, and/or diamond-shaped pillars 308C. The features of memory array 300C may be larger than the features of memory arrays 300A and 300B. In some embodiments, the diamond-shaped pillar 308C has a width (e.g., the left-to-right dimension as illustrated) between approximately 735 nanometers and approximately 785 nanometers and a height (e.g., the top-to-bottom dimensions as illustrated) between approximately 350 nanometers and approximately 400 nanometers. In some embodiments, the minimum distance between the diamond-shaped pillar 308C and the adjacent live contacts 304C is between approximately 95 nanometers and approximately 125 nanometers. The dimensions of the live contacts 304C and/or the dummy contacts 306C may be commensurate with the dimensions of the diamond-shaped pillar 308C.

Trenches 302 may have the same dimensions (e.g., width) for each of memory arrays 300A, 300B, and 300C. In some embodiments, the diamond-shaped pillar can have a width between approximately 550 nanometers and approximately 785 nanometers. In some embodiments, the diamond-shaped pillar can have a height between approximately 290 nanometers and approximately 400 nanometers. In some embodiments, the minimum distance between the diamond-shaped pillar and the adjacent live contacts is between approximately 95 nanometers and approximately 160 nanometers.

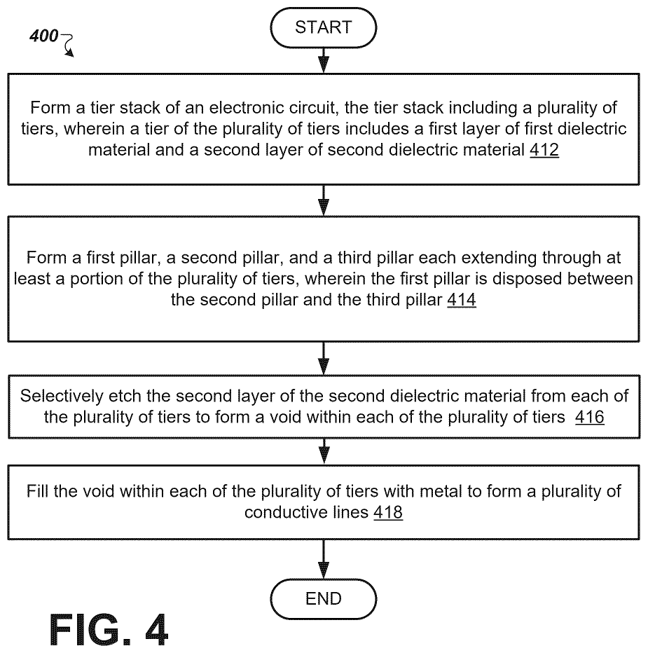

FIG. 4 is a flow diagram of an example method 400 of manufacturing an electronic device such as a memory array in accordance with some embodiments of the present disclosure. Although shown in a particular sequence or order, unless otherwise specified, the order of the processes can be modified. Thus, the illustrated embodiments should be understood only as examples, and the illustrated processes can be performed in a different order, and some processes can be performed in parallel. Additionally, one or more processes can be omitted in various embodiments. Thus, not all processes are required in every embodiment. Other process flows are possible.

At block 412, a tier stack of an electronic circuit is formed. In some embodiments, the electronic circuit is a memory array such as a flash memory array, a 3D NAND memory array, etc. In some embodiments, the tier stack includes a plurality of tiers. A tier may include a first layer of first dielectric material and a second layer of second dielectric material. In some embodiments, the tier stack is formed by multiple deposition processes. For example, a first deposition process may be performed to form a first first layer, a second deposition process may be performed to form a first second layer, a third deposition process may be performed to form a second first layer, and so on. In some embodiments, the first layer is a metalloid oxide layer (e.g., a silicon oxide layer) and the second layer is a metalloid nitride layer (e.g., a silicon nitride layer).

At block 414, multiple pillars are formed in the tier stack. In some embodiments, a first pillar, a second pillar, and a third pillar are formed each extending through at least a portion of the plurality of tiers. In some embodiments, the first pillar, the second pillar, and/or the third pillar extend orthogonally through at least a portion of the plurality of tiers. The first pillar may be disposed between the second pillar and the third pillar in the tier stack. In some embodiments, the first pillar, the second pillar, and the third pillar form a structural support system within the tier stack. For example, the first pillar, the second pillar, and the third pillar may structurally support the first layers of the tiers when the second layers are exhumed leaving voids between the first layers. The first pillar, second pillar, and third pillar may provide stability, strength, rigidity, and/or reinforcement to the first layers. In some embodiments, the first pillar, second pillar, and third pillar may support the first layers so that the first layers do not collapse onto one another and/or so that the first layers substantially do not deflect during manufacturing process(es) as described herein. In some embodiments, the first pillar has a diamond-shaped cross-section as described herein. In some embodiments, the first pillar, the second pillar, and the third pillar are formed by forming holes (e.g., recesses) in the tier stack and filling the holes with a dielectric material such as carbon or poly-silicon. The first, second, and third pillars may be formed during formation of contacts. For example, the holes formed for the pillars may be etched concurrently with holes etched for live contacts. After being filled with dielectric material, the first pillar, the second pillar, and the third pillar may form dummy contacts.

At block 416, the second layer of the second dielectric material is selectively etched from each of the plurality of tiers to form a void within each of the plurality of tiers. In some embodiments, an etch process is performed to etch the second dielectric material selective to the first dielectric material. For example, an etchant may be introduced that etches silicon nitride without etching silicon oxide, poly-silicon, and/or carbon, etc.

At block 418, the void within each of the plurality of tiers is filled with metal to form a plurality of conductive lines. In some embodiments, metal (e.g., a metal-containing precursor, molten metal, etc.) is introduced into the voids. The metal may grow and/or solidify within the voids to form conductive lines. In some embodiments, the metal is a conductive metal such as a molybdenum alloy or a tungsten alloy.

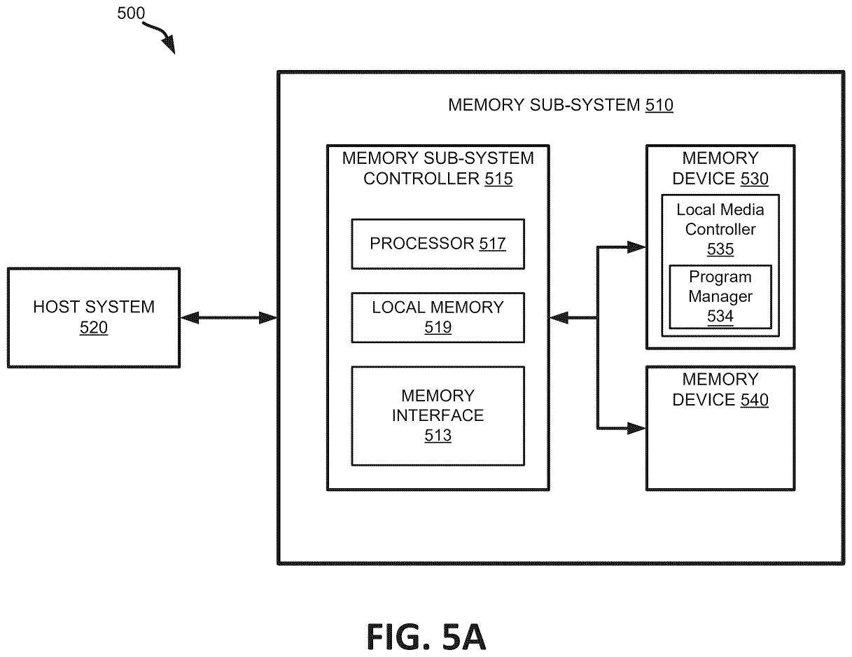

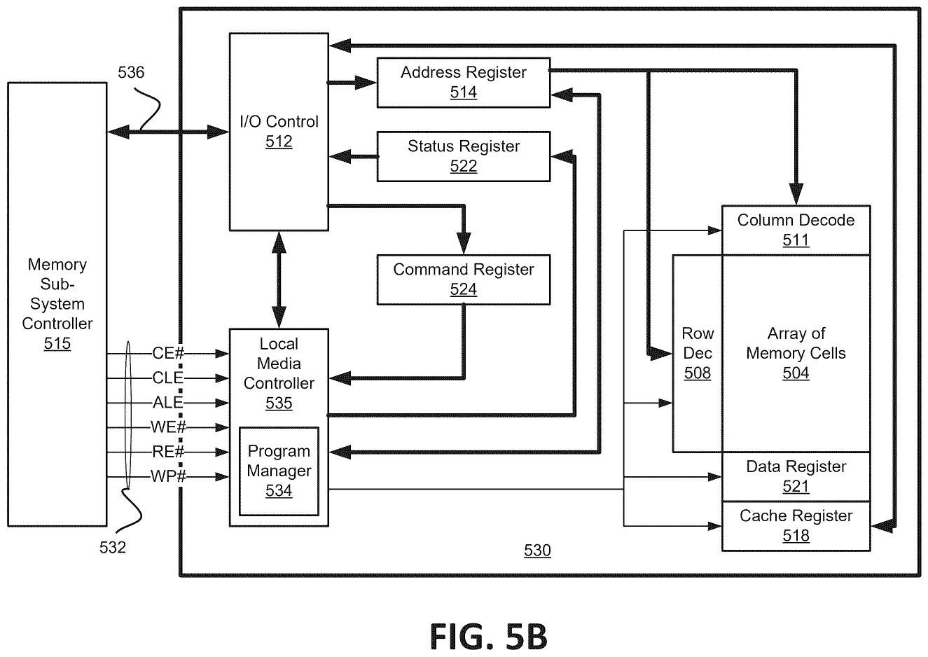

FIG. 5A illustrates an example computing system 500 that includes a memory sub-system 510 in accordance with some embodiments of the present disclosure. In some embodiments, one or more components of computing system 500 include support pillars as described herein above. The memory sub-system 510 can include media, such as one or more volatile memory devices (e.g., memory device 540), one or more non-volatile memory devices (e.g., memory device 530), or a combination of such.

A memory sub-system 510 can be a storage device, a memory module, or a combination of a storage device and memory module. Examples of a storage device include a solid-state drive (SSD), a flash drive, a universal serial bus (USB) flash drive, an embedded Multi-Media Controller (eMMC) drive, a Universal Flash Storage (UFS) drive, a secure digital (SD) card, and a hard disk drive (HDD). Examples of memory modules include a dual in-line memory module (DIMM), a small outline DIMM (SO-DIMM), and various types of non-volatile dual in-line memory modules (NVDIMMs).

The computing system 500 can be a computing device such as a desktop computer, laptop computer, network server, mobile device, a vehicle (e.g., airplane, drone, train, automobile, or other conveyance), Internet of Things (IoT) enabled device, embedded computer (e.g., one included in a vehicle, industrial equipment, or a networked commercial device), or such computing device that includes memory and a processing device.

The computing system 500 can include a host system 520 that is coupled to one or more memory sub-systems 510. In some embodiments, the host system 520 is coupled to multiple memory sub-systems 510 of different types. FIG. 5A illustrates one example of a host system 520 coupled to one memory sub-system 510. As used herein, “coupled to” or “coupled with” generally refers to a connection between components, which can be an indirect communicative connection or direct communicative connection (e.g., without intervening components), whether wired or wireless, including connections such as electrical, optical, magnetic, etc.

The host system 520 can include a processor chipset and a software stack executed by the processor chipset. The processor chipset can include one or more cores, one or more caches, a memory controller (e.g., NVDIMM controller), and a storage protocol controller (e.g., PCIe controller, SATA controller). The host system 520 uses the memory sub-system 510, for example, to write data to the memory sub-system 510 and read data from the memory sub-system 510.

The host system 520 can be coupled to the memory sub-system 510 via a physical host interface. Examples of a physical host interface include a serial advanced technology attachment (SATA) interface, a peripheral component interconnect express (PCIe) interface, universal serial bus (USB) interface, Fibre Channel, Serial Attached SCSI (SAS), a double data rate (DDR) memory bus, Small Computer System Interface (SCSI), a dual in-line memory module (DIMM) interface (e.g., DIMM socket interface that supports Double Data Rate (DDR)), etc. The physical host interface can be used to transmit data between the host system 520 and the memory sub-system 510. The host system 520 can further utilize an NVM Express (NVMe) interface to access components (e.g., memory devices 530) when the memory sub-system 510 is coupled with the host system 520 by the physical host interface (e.g., PCIe bus). The physical host interface can provide an interface for passing control, address, data, and other signals between the memory sub-system 510 and the host system 520. FIG. 5A illustrates a memory sub-system 510 as an example. In general, the host system 520 can access multiple memory sub-systems via a same communication connection, multiple separate communication connections, and/or a combination of communication connections.

The memory devices 530, 540 can include any combination of the different types of non-volatile memory devices and/or volatile memory devices. The volatile memory devices (e.g., memory device 540) can be random access memory (RAM), such as dynamic random access memory (DRAM) and synchronous dynamic random access memory (SDRAM).

Some examples of non-volatile memory devices (e.g., memory device 530) include a negative-and (NAND) type flash memory and write-in-place memory, such as a three-dimensional cross-point (“3D cross-point”) memory device, which is a cross-point array of non-volatile memory cells. A cross-point array of non-volatile memory cells can perform bit storage based on a change of bulk resistance, in conjunction with a stackable cross-gridded data access array. Additionally, in contrast to many flash-based memories, cross-point non-volatile memory can perform a write in-place operation, where a non-volatile memory cell can be programmed without the non-volatile memory cell being previously erased. NAND type flash memory includes, for example, two-dimensional NAND (2D NAND) and three-dimensional NAND (3D NAND).

Each of the memory devices 530 can include one or more arrays of memory cells. One type of memory cell, for example, single level cells (SLC) can store one bit per cell. Other types of memory cells, such as multi-level cells (MLCs), triple level cells (TLCs), quad-level cells (QLCs), and penta-level cells (PLCs) can store multiple bits per cell. In some embodiments, each of the memory devices 530 can include one or more arrays of memory cells such as SLCs, MLCs, TLCs, QLCs, PLCs or any combination of such. In some embodiments, a particular memory device can include an SLC portion, and an MLC portion, a TLC portion, a QLC portion, or a PLC portion of memory cells. The memory cells of the memory devices 530 can be grouped as pages that can refer to a logical unit of the memory device used to store data. With some types of memory (e.g., NAND), pages can be grouped to form blocks.

Although non-volatile memory components such as a 3D cross-point array of non-volatile memory cells and NAND type flash memory (e.g., 2D NAND, 3D NAND) are described, the memory device 530 can be based on any other type of non-volatile memory, such as read-only memory (ROM), phase change memory (PCM), self-selecting memory, other chalcogenide based memories, ferroelectric transistor random-access memory (FeTRAM), ferroelectric random access memory (FeRAM), magneto random access memory (MRAM), Spin Transfer Torque (STT)-MRAM, conductive bridging RAM (CBRAM), resistive random access memory (RRAM), oxide based RRAM (OxRAM), negative-or (NOR) flash memory, or electrically erasable programmable read-only memory (EEPROM).

A memory sub-system controller 515 (or controller 515 for simplicity) can communicate with the memory devices 530 to perform operations such as reading data, writing data, or erasing data at the memory devices 530 and other such operations. The memory sub-system controller 515 can include hardware such as one or more integrated circuits and/or discrete components, a buffer memory, or a combination thereof. The hardware can include a digital circuitry with dedicated (i.e., hard-coded) logic to perform the operations described herein. The memory sub-system controller 515 can be a microcontroller, special purpose logic circuitry (e.g., a field programmable gate array (FPGA), an application specific integrated circuit (ASIC), etc.), or other suitable processor.

The memory sub-system controller 515 can include a processing device, which includes one or more processors (e.g., processor 517), configured to execute instructions stored in a local memory 519. In the illustrated example, the local memory 519 of the memory sub-system controller 515 includes an embedded memory configured to store instructions for performing various processes, operations, logic flows, and routines that control operation of the memory sub-system 510, including handling communications between the memory sub-system 510 and the host system 520.

In some embodiments, the local memory 519 can include memory registers storing memory pointers, fetched data, etc. The local memory 519 can also include read-only memory (ROM) for storing micro-code. While the example memory sub-system 510 in FIG. 5A has been illustrated as including the memory sub-system controller 515, in another embodiment of the present disclosure, a memory sub-system 510 does not include a memory sub-system controller 515, and can instead rely upon external control (e.g., provided by an external host, or by a processor or controller separate from the memory sub-system).

In general, the memory sub-system controller 515 can receive commands or operations from the host system 520 and can convert the commands or operations into instructions or appropriate commands to achieve the desired access to the memory devices 530. The memory sub-system controller 515 can be responsible for other operations such as wear leveling operations, garbage collection operations, error detection and error-correcting code (ECC) operations, encryption operations, caching operations, and address translations between a logical address (e.g., a logical block address (LBA), namespace) and a physical address (e.g., physical block address) that are associated with the memory devices 530. The memory sub-system controller 515 can further include host interface circuitry to communicate with the host system 520 via the physical host interface. The host interface circuitry can convert the commands received from the host system into command instructions to access the memory devices 530 as well as convert responses associated with the memory devices 530 into information for the host system 520.

The memory sub-system 510 can also include additional circuitry or components that are not illustrated. In some embodiments, the memory sub-system 510 can include a cache or buffer (e.g., DRAM) and address circuitry (e.g., a row decoder and a column decoder) that can receive an address from the memory sub-system controller 515 and decode the address to access the memory devices 530.

In some embodiments, the memory devices 530 include local media controllers 535 that operate in conjunction with memory sub-system controller 515 to execute operations on one or more memory cells of the memory devices 530. An external controller (e.g., memory sub-system controller 515) can externally manage the memory device 530 (e.g., perform media management operations on the memory device 530). In some embodiments, memory sub-system 510 is a managed memory device, which is a raw memory device 530 having control logic (e.g., local media controller 535) on the die and a controller (e.g., memory sub-system controller 515) for media management within the same memory device package. An example of a managed memory device is a managed NAND (MNAND) device.

The memory sub-system 510 includes a memory interface component 513 that can handle interactions of memory sub-system controller 515 with the memory devices of memory sub-system 510, such as memory device 530. For example, memory interface component 513 can receive data from memory device 530, such as data retrieved in response to a read operation or a write operation. In some examples, the memory sub-system controller 515 can include a processor 517 (processing device) configured to execute instructions stored in local memory 519 for performing the operations described herein.

In some embodiments, memory device 530 includes a program manager 534. In some embodiments, local media controller 535 includes at least a portion of program manager 534 and is configured to perform various memory functions. In some embodiments, the program manager 534 is part of the host system 510, an application, or an operating system. Further details with regards to the operations of program manager 534 are described below. In some embodiments, program manager 534 is implemented on memory device 530 using firmware, hardware components, or a combination of the above.

FIG. 5B is a simplified block diagram of a first apparatus, in the form of a memory device 530, in communication with a second apparatus, in the form of a memory sub-system controller 515 of a memory sub-system (e.g., memory sub-system 510 of FIG. 5A), according to an embodiment. In some embodiments, one or more components of memory device 530 include conductive lines manufactured according to a method described herein above. Some examples of electronic systems include personal computers, personal digital assistants (PDAs), digital cameras, digital media players, digital recorders, games, appliances, vehicles, wireless devices, mobile telephones and the like. The memory sub-system controller 515 (e.g., a controller external to the memory device 530), can be a memory controller or other external host device.

Memory device 530 includes an array of memory cells 504 logically arranged in rows and columns. Memory cells of a logical row are typically connected to the same access line (e.g., a wordline) while memory cells of a logical column are typically selectively connected to the same data line (e.g., a bit line). A single access line can be associated with more than one logical row of memory cells and a single data line can be associated with more than one logical column. Memory cells (not shown in FIG. 5B) of at least a portion of array of memory cells 504 are capable of being programmed to one of at least two target data states.

Row decode circuitry 508 and column decode circuitry 511 are provided to decode address signals. Address signals are received and decoded to access the array of memory cells 504. Memory device 530 also includes input/output (I/O) control circuitry 512 to manage input of commands, addresses and data to the memory device 530 as well as output of data and status information from the memory device 530. An address register 514 is in communication with I/O control circuitry 512 and row decode circuitry 508 and column decode circuitry 511 to latch the address signals prior to decoding. A command register 524 is in communication with I/O control circuitry 512 and local media controller 535 to latch incoming commands.

A controller (e.g., the local media controller 535 internal to the memory device 530) controls access to the array of memory cells 504 in response to the commands and generates status information for the external memory sub-system controller 515, i.e., the local media controller 535 is configured to perform access operations (e.g., read operations, programming operations and/or erase operations) on the array of memory cells 504. The local media controller 535 is in communication with row decode circuitry 508 and column decode circuitry 511 to control the row decode circuitry 508 and column decode circuitry 511 in response to the addresses. In at least one embodiment, local media controller 535 includes program manager 534, which can implement the bad block mapping operations with respect to memory device 530, as described herein.

The local media controller 535 is also in communication with a cache register 518. Cache register 518 latches data, either incoming or outgoing, as directed by the local media controller 535 to temporarily store data while the array of memory cells 504 is busy writing or reading, respectively, other data. During a programming operation (e.g., a write operation), data can be passed from the cache register 518 to the data register 521 for transfer to the array of memory cells 504; then new data can be latched in the cache register 518 from the I/O control circuitry 512. During a read operation, data can be passed from the cache register 518 to the I/O control circuitry 512 for output to the memory sub-system controller 515; then new data can be passed from the data register 521 to the cache register 518. The cache register 518 and/or the data register 521 can form (e.g., can form a portion of) a page buffer of the memory device 530. A page buffer can further include sensing devices (not shown in FIG. 5B) to sense a data state of a memory cell of the array of memory cells 504, e.g., by sensing a state of a data line connected to that memory cell. A status register 522 can be in communication with I/O control circuitry 512 and the local memory controller 535 to latch the status information for output to the memory sub-system controller 515.

Memory device 530 receives control signals at the memory sub-system controller 515 from the local media controller 535 over a control link 532. For example, the control signals can include a chip enable signal CE#, a command latch enable signal CLE, an address latch enable signal ALE, a write enable signal WE#, a read enable signal RE#, and a write protect signal WP#. Additional or alternative control signals (not shown) can be further received over control link 532 depending upon the nature of the memory device 530. In at least one embodiment, memory device 530 receives command signals (which represent commands), address signals (which represent addresses), and data signals (which represent data) from the memory sub-system controller 515 over a multiplexed input/output (I/O) bus 536 and outputs data to the memory sub-system controller 515 over I/O bus 536.

For example, the commands can be received over input/output (I/O) pins [7:0] of I/O bus 536 at I/O control circuitry 512 and can then be written into command register 524. The addresses can be received over input/output (I/O) pins [7:0] of I/O bus 536 at I/O control circuitry 512 and can then be written into address register 514. The data can be received over input/output (I/O) pins [7:0] for an 8-bit device or input/output (I/O) pins [15:0] for a 16-bit device at I/O control circuitry 512 and then can be written into cache register 518. The data can be subsequently written into data register 521 for programming the array of memory cells 504.

In at least one embodiment, cache register 518 can be omitted, and the data can be written directly into data register 521. Data can also be output over input/output (I/O) pins [7:0] for an 8-bit device or input/output (I/O) pins [15:0] for a 16-bit device. Although reference can be made to I/O pins, they can include any conductive node providing for electrical connection to the memory device 530 by an external device (e.g., the memory sub-system controller 515), such as conductive pads or conductive bumps as are commonly used.

In some implementations, additional circuitry and signals can be provided, and that the memory device 530 of FIG. 5B has been simplified. It should be recognized that the functionality of the various block components described with reference to FIG. 5B cannot necessarily be segregated to distinct components or component portions of an integrated circuit device. For example, a single component or component portion of an integrated circuit device could be adapted to perform the functionality of more than one block component of FIG. 5B. Alternatively, one or more components or component portions of an integrated circuit device could be combined to perform the functionality of a single block component of FIG. 5B. Additionally, while specific I/O pins are described in accordance with popular conventions for receipt and output of the various signals, it is noted that other combinations or numbers of I/O pins (or other I/O node structures) can be used in the various embodiments.

The preceding description sets forth numerous specific details such as examples of specific systems, components, methods, and so forth, in order to provide a good understanding of several embodiments of the present disclosure. It will be apparent to one skilled in the art, however, that at least some embodiments of the present disclosure may be practiced without these specific details. In other instances, well-known components or methods are not described in detail or are presented in simple block diagram format in order to avoid unnecessarily obscuring the present disclosure. Thus, the specific details set forth are merely exemplary. Particular embodiments may vary from these exemplary details and still be contemplated to be within the scope of the present disclosure.

As used herein, the singular forms “a,” “an,” and “the” include plural references unless the context clearly indicates otherwise. Thus, for example, reference to “a precursor” includes a single precursor as well as a mixture of two or more precursors; and reference to a “reactant” includes a single reactant as well as a mixture of two or more reactants, and the like.

Reference throughout this specification to “one embodiment” or “an embodiment” means that a particular feature, structure, or characteristic described in connection with the embodiment is included in at least one embodiment. Thus, the appearances of the phrase “in one embodiment” or “in an embodiment” in various places throughout this specification are not necessarily all referring to the same embodiment. In addition, the term “or” is intended to mean an inclusive “or” rather than an exclusive “or.” When the term “about” or “approximately” is used herein, this is intended to mean that the nominal value presented is precise within ±10%, such that “about 10” would include from 9 to 11.

The term “at least about” in connection with a measured quantity refers to the normal variations in the measured quantity, as expected by one of ordinary skill in the art in making the measurement and exercising a level of care commensurate with the objective of measurement and precisions of the measuring equipment and any quantities higher than that. In certain embodiments, the term “at least about” includes the recited number minus 10% and any quantity that is higher such that “at least about 10” would include 9 and anything greater than 9. This term can also be expressed as “about 10 or more.” Similarly, the term “less than about” typically includes the recited number plus 10% and any quantity that is lower such that “less than about 10” would include 11 and anything less than 11. This term can also be expressed as “about 10 or less.”

Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to illuminate certain materials and methods and does not pose a limitation on scope. No language in the specification should be construed as indicating any non-claimed element as essential to the practice of the disclosed materials and methods.

Although the operations of the methods herein are shown and described in a particular order, the order of the operations of each method may be altered so that certain operations may be performed in an inverse order or so that certain operation may be performed, at least in part, concurrently with other operations. In another embodiment, instructions or sub-operations of distinct operations may be in an intermittent and/or alternating manner.

It is to be understood that the above description is intended to be illustrative, and not restrictive. Many other embodiments will be apparent to those of skill in the art upon reading and understanding the above description. The scope of the disclosure should, therefore, be determined with reference to the appended claims, along with the full scope of equivalents to which such claims are entitled.

What is claimed is:

1. A method, comprising:
forming a tier stack of an electronic circuit, the tier stack comprising a plurality of tiers, wherein a tier of the plurality of tiers comprises a first layer of a first dielectric material and a second layer of a second dielectric material;
forming a first pillar, a second pillar, and a third pillar, each extending through at least a portion of the plurality of tiers, wherein the first pillar is disposed between the second pillar and the third pillar;
selectively etching the second layer of the second dielectric material of each of the plurality of tiers to form a void within each of the plurality of tiers; and
filling the void within each of the plurality of tiers with metal to form a plurality of conductive lines.

2. The method of claim 1, wherein forming the first pillar, the second pillar, and the third pillar comprises:
forming a first recess, a second recess, and a third recess in the tier stack; and
filling the first recess, the second recess, and the third recess each with a third dielectric material, wherein the first pillar, the second pillar, and the third pillar comprise the third dielectric material within the first recess, the second recess, and the third recess respectively.

3. The method of claim 2, wherein the third dielectric material comprises at least one of carbon or poly-silicon.

4. The method of claim 1, wherein the pillar supports the first layers of the plurality of tiers after the second layers of the plurality of tiers are selectively etched.

5. The method of claim 1, wherein at least the first pillar forms a dummy contact, and wherein a fourth pillar formed in the tier stack forms a live contact.

6. The method of claim 1, wherein the first pillar has a diamond-shaped cross-section.

7. The method of claim 6, wherein the diamond-shaped cross-section comprises at least partially rounded corners.

8. The method of claim 1, wherein the first dielectric material comprises a metalloid oxide and wherein the second dielectric material comprises a metalloid nitride.

9. The method of claim 1, wherein the metal comprises a molybdenum alloy or a tungsten alloy.

10. The method of claim 1, wherein the electronic circuit comprises a memory array.

11. A memory array, comprising:
a stack of layers; and
a first pillar, a second pillar, and a third pillar each extending through at least a portion of the stack of layers, wherein the first pillar is disposed between the second pillar and the third pillar, wherein at least the first pillar supports a first layer of the stack of layers, and wherein the first pillar is formed of a first dielectric material.

12. The memory array of claim 11, wherein at least the first pillar forms a dummy contact, and wherein a fourth pillar formed in the stack of layers forms a live contact.

13. The memory array of claim 11, wherein the first pillar has a diamond-shaped cross-section.

14. The memory array of claim 13, wherein the diamond-shaped cross-section comprises at least partially rounded corners.

15. The memory array of claim 11, wherein the stack of layers comprises alternating layers of a second dielectric material and a conductive material.

16. The memory array of claim 15, wherein the second dielectric material comprises a metalloid oxide, and wherein the conductive material comprises a molybdenum alloy or a tungsten alloy.

17. An electronic device, comprising:
a tier stack comprising a plurality of tiers, wherein a tier of the plurality of tiers comprises a first layer of first dielectric material and a second layer of conductive material; and
multiple pillars extending through at least a portion of the plurality of tiers, wherein at least a first pillar of the multiple pillars is disposed between two or more second pillars, wherein at least the first pillar supports the first layers of the plurality of tiers.

18. The electronic device of claim 17, wherein the first pillar forms a dummy contact, and wherein at least one of the second pillars forms a live contact.

19. The electronic device of claim 17, wherein the first pillar has a diamond-shaped cross-section, and wherein the diamond-shaped cross-section comprises at least partially rounded corners.

20. The electronic device of claim 17, wherein the first dielectric material comprises a metalloid oxide, wherein the conductive material comprises a molybdenum alloy or a tungsten alloy, and wherein the first pillar comprises a second dielectric material.
